(19) United States
(12) Patent Application Publication
(10) Pub. No.: US 2025/0204007 A1
(43) Pub. Date: Jun. 19, 2025

(54) Semiconductor structure and forming method thereof

(71) Applicant: United Microelectronics Corp., Hsin-Chu-City (TW)

(72) Inventors: Chun-Wen Cheng, New Taipei City (TW); Ming-Hua Tsai, Tainan City (TW); Chun-Lin Chen, Tainan City (TW); Ming-Hsiang Tu, Tainan City (TW); Ya-Hsin Huang, Tainan City (TW); Yung-Fang Yang, Chiayi City (TW)

(73) Assignee: United Microelectronics Corp., Hsin-Chu-City (TW)

(21) Appl. No.: 18/413,051

(22) Filed: Jan. 16, 2024

(30) Foreign Application Priority Data
Dec. 13, 2023 (TW) 112148531

(51) Int. Cl. H01L 29/423; H01L 29/06; H01L 29/40

(52) U.S. Cl. CPC H10D 64/514; H10D 62/124; H10D 64/01

(57) ABSTRACT

The invention provides a semiconductor structure, which comprises a substrate, a high-voltage device region is defined on the substrate, in the high-voltage device region, the substrate comprises a first region, a first groove surrounds the first region, and a second region surrounds the first groove, and a contact gate structure is located in the high-voltage device region, when viewed from a top view, the contact gate structure comprises a plurality of columnar dielectric layers arranged in an array.

### BACKGROUND OF THE INVENTION

### 1. Field of the Invention

The invention relates to the field of semiconductor manufacturing, in particular to a special gate structure in a high-voltage device region in semiconductor manufacturing.

### 2. Description of the Prior Art

In the semiconductor manufacturing process, the fineness of the nano-process is generally described in nanometers. For example, the 14-nanometer process means that the lowest line width that can be formed in the semiconductor process is 14 nanometers. With the progress of process technology, the line width of nano-process is gradually reduced.

However, even with the progress of nano-fabrication, not all devices are suitable for high-precision nano-fabrication. For example, when the size of the device does not match the precision of the nano-process, it will not only lead to the decline of the yield of the device, but also consume more costs. Therefore, in order to adapt to components with different sizes or precisions, different components will be formed by nano-processes with different precisions. On a wafer, there may be components with different precisions in different areas at the same time, but at the same time, various structural problems may easily occur.

### SUMMARY OF THE INVENTION

The invention provides a semiconductor structure, which comprises a substrate, wherein a high-voltage device region is defined on the substrate, wherein the substrate of the high-voltage device region comprises a first region, a first groove surrounds the first region, and a second region surrounds the first groove, and a contact gate structure is located in the high-voltage device region, wherein, from a top view, the contact gate structure comprises a plurality of columnar dielectric layers arranged in an array.

The invention also provides a method for forming a semiconductor structure, which comprises providing a substrate with a high-voltage device region defined thereon, wherein the substrate of the high-voltage device region comprises a first region, a first groove surrounding the first region and a second region surrounding the first groove, and forming a contact gate structure in the high-voltage device region, wherein the contact gate structure comprises a plurality of columnar dielectric layers arranged in an array from a top view.

The present invention is characterized by providing a semiconductor structure with a high-voltage device region and a logic region, wherein the gate structure of the high-voltage device region is not formed by the conventional gate patterning steps and processes such as replacing metal gates (including forming a gate sacrificial layer, defining the gate position, removing the gate sacrificial layer to form a gate groove, filling a plurality of layers of materials into the gate groove, etc.), but is formed at the same time as the slot contact structure. Therefore, the gate structure in the high-voltage device region is composed of a single layer of metal, which includes a plurality of columnar dielectric layers arranged in an array, and the two sides of the gate structure do not include spacers. The gate electrode in the high-voltage device region of the invention has good electrical properties, and it is not easy to produce phenomena such as dishing in the manufacturing process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIGS. 1 to 11 are schematic cross-sectional views of a semiconductor structure of the present invention in a high-voltage device region and a logic region, respectively, wherein:

FIG. 1 is a schematic cross-sectional view of a substrate in a high-voltage device region and a logic region after an oxide layer and a gate sacrificial layer are formed;

FIG. 2 is a schematic diagram showing the cross-sectional structure after the gate definition step in the logic region;

FIG. 3 is a schematic diagram showing the cross-sectional structure after the spacer material layer is formed;

FIG. 4 is a schematic diagram showing the cross-sectional structure after the epitaxial layer is formed in the logic region;

FIG. 5 is a schematic diagram showing the cross-sectional structure after forming a contact etch stop material layer and a dielectric layer;

FIG. 6 is a schematic cross-sectional view showing the planarization step;

FIG. 7 shows a schematic cross-sectional structure after removing the gate sacrificial layer in the logic region;

FIG. 8 is a schematic cross-sectional view showing the formation of a multi-layer material layers, and the multi-layer material layers are filled in the gate groove in the logic region;

FIG. 9 is a schematic cross-sectional view showing another planarization step;

FIG. 10 shows a schematic cross-sectional structure after another dielectric layer is formed;

FIG. 11 shows a schematic cross-sectional structure after contact structures and a contact gate structure are formed.

FIG. 12 is a partial top view of the contact gate structure in the high-voltage device region of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

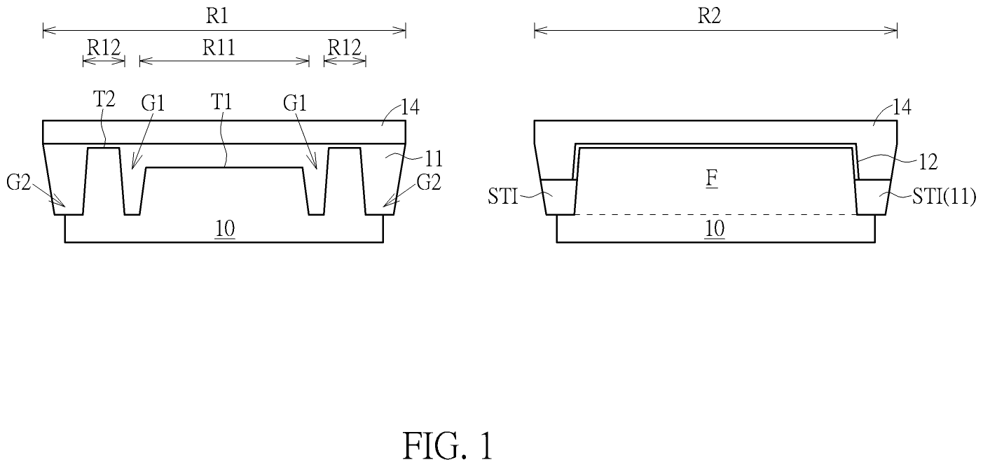

Please refer to FIG. 1, which shows a schematic cross-sectional structure after an oxide layer and a gate sacrificial layer are formed on a substrate in a high-voltage device region and a logic region. As shown in FIG. 1, the semiconductor structure 10 of the present invention includes a high-voltage device region R1 and a logic region R2, the two regions may be adjacent to each other, or the two regions may not be adjacent to each other (there may be a blank region or other regions between them). The difference between the high-voltage device region R1 and the logic region R2 is that the operating voltages of the elements contained therein are different. Generally speaking, taking a display chip as an example, the logic region R2 includes, for example, a logic operation circuit, the operating voltage of which is below 5 volts, and preferably within 1.5 volts. On the contrary, the operating voltage of the electronic elements included in the high-voltage device region R1 is more than 5 volts, usually more than 10 volts. For example, a driving element in a display wafer needs a higher voltage to drive the elements therein, and these elements belong to the high voltage elements of the present invention.

When the nano-precision of semiconductor process is improved, it means that the size of devices is getting smaller and smaller, and devices can also develop towards three-dimensional structure to increase the density per unit area. In this embodiment, the logic region R2 contains a plurality of fin structures F, while the high-voltage device region R1 is dominated by planar structures.

As mentioned in the prior art, different devices on the same chip will form devices with different operating voltages in different regions on the same chip because of their different sizes or applications. However, in the actual manufacturing process, structural problems will easily occur. For example, gate structures need to be formed in the high-voltage device region R1 and the logic region R2. In the conventional process steps, the gate structures in the two regions are made of the same material (including, for example, a high dielectric constant layer, a work function metal layer, a gate conductive layer, etc.). However, because the size of the gate structure in the high-voltage device region R1 is different from that in the logic region R2, the size of the gate structure in the high-voltage device region R1 is usually larger, so it is easy to generate a dishing phenomenon in the planarization step (such as chemical mechanical polishing), or it is easy to leave metal after the planarization step. All of the above are defects in the manufacturing process.

In order to solve the above problems, the present invention provides a semiconductor structure, in which the gate structure in the high-voltage device region is manufactured by a single-layer metal process and simultaneously with the slot contact structures. Therefore, the gate structure in the high-voltage device region has a special shape and its material is not easy to be worn, which can improve the quality of the device. Details are described in the following paragraphs.

Referring to FIG. 1, as shown in FIG. 1, a substrate 10, such as a silicon substrate, is provided, and a high-voltage device region R1 and a logic region R2 are defined on the substrate 10, wherein the shape of the substrate 10 in the high-voltage device region R1 is different from the shape of the substrate 10 in the logic region R2, and more specifically, the high-voltage device region R1 further includes a first region R11 and a second region R12, wherein the first region R11 is, for example, a region where a gate is formed in a subsequent step, and the second region R12 is, for example, the source/drain and the contact structures formed in a subsequent step. Seen from the sectional view, a top surface T1 of the first region R11 is lower than a top surface T2 of the second region R12. In addition, the high-voltage device region R1 also includes a first groove G1 surrounding the first region R11, that is, the first groove G1 is between the first region R11 and the second region R12. The bottom surface of the first groove G1 is lower than the top surface T1 of the first region R11. In addition, a second groove G2 is included around the periphery of the second region R12, and the depth of the bottom surface of the second groove G2 may be the same as or different from that of the first groove G1, the present invention is not limited to this. For example, the substrate 10 in the high-voltage device region R1 can be patterned and etched to form the structure as shown in FIG. 1, and the related technologies are known in the field, so it will not be repeated here.

As for the logic area R2, the substrate 10 contains a fin structure F, wherein the material of the fin structure F can be the same as that of the substrate 10 (for example, silicon). The fin structure F protrudes from the surface of the substrate 10. For example, the fabrication method of the fin structure F forms a three-dimensional outline on the substrate 10 by patterning and etching, and the related technologies belong to the prior art in this field, so it will not be repeated here.

In the following steps, required devices, such as transistor structures, are formed in the high-voltage device region R1 and the logic region R2, respectively, wherein the transistor structure in the high-voltage device region R1 is a planar structure, while the transistor structure in the logic region R2 is a three-dimensional structure because it straddles the fin structure F.

Then, an insulating layer 11 is formed to cover the substrate 10. The insulating layer 11 is made of silicon oxide, silicon nitride or silicon oxynitride, for example, but the present invention is not limited to this. In the high-voltage device region R1, the insulating layer 11 covers the first region R11, the second region R12, the first groove G1 and the second groove G2. Similarly, the insulating layer 11 will also cover the fin structure F in the logic region R2 and the substrate 10. However, an etching back step is further performed in the logic region R2 to remove part of the insulating layer 11 and expose the top surface of the fin structure F. At this time, the remaining insulating layers 11 in the logic region R2 surround the fin structure F, and these remaining insulating layers 11 can be defined as shallow trench isolation STI.

Next, an oxide layer 12 and a gate sacrificial layer 14 are formed. For example, the oxide layer 12 is formed on the surface of the fin structure F in the logic region R2 by thermal oxidation step, or the oxide layer 12 can be formed on the surface of the insulating layer 11 in the high-voltage device region R1, the shallow trench isolation STI surface in the logic region R2 and the surface of the fin structure F by deposition step, the present invention is not limited to this. The gate sacrificial layer 14 is formed by deposition, for example, and its material is polysilicon, but it is not limited to this. In addition, it is worth noting that the oxide layer 12 here can be used as the gate oxide layer of the transistor formed in the logic region R2, and the transistor formed in the high-voltage device region R1 uses the insulating layer 11 in the first region R11 as the gate oxide layer.

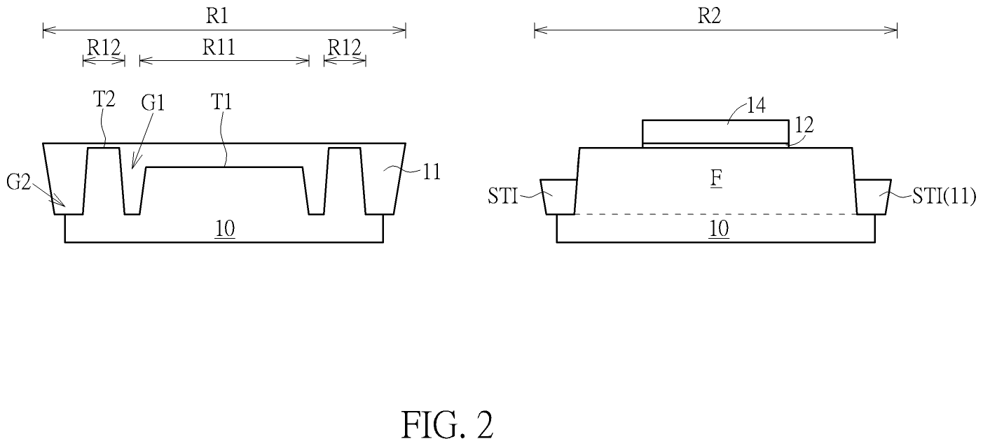

FIG. 2 shows a schematic cross-sectional structure after the gate definition step in the logic region. As shown in FIG. 2, a gate defining step is performed to remove part of the gate sacrificial layer 14 and oxide layer 12 in the high-voltage device region R1 and the logic region R2, leaving part of the oxide layer 12 and the gate sacrificial layer 14 in the logic region R2. In this step, the position of the gate sacrificial layer 14 left in the logic region R2 corresponds to the position of the subsequent gate structure, that is to say, the position of the gate sacrificial layer 14 left here will be replaced by a metal gate in the future.

It is worth noting that during the gate definition step, the gate is not defined in the high-voltage device region R1, that is, after the gate definition step, the gate sacrificial layer 14 is not left in the high-voltage device region R1, and both the oxide layer 12 and the gate sacrificial layer 14 in the high-voltage device region R1 are completely removed. In other words, the gate structure subsequently formed in the high-voltage device region R1 of the present invention does not use the gate definition step in the logic region to define its position. The details will be explained in the following paragraphs.

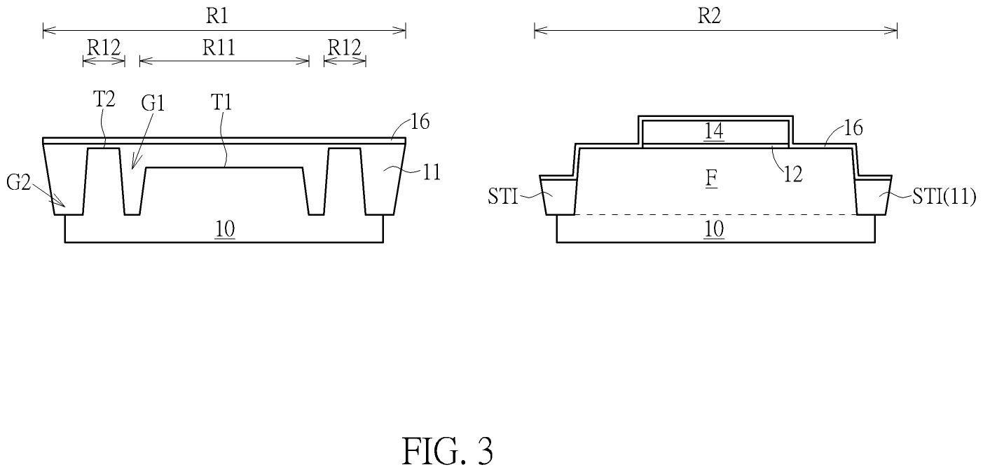

FIG. 3 shows a schematic cross-sectional structure after forming a spacer material layer. As shown in FIG. 3, a spacer material layer 16 is formed, and the material of the spacer material layer 16 is, for example, silicon oxide, silicon nitride or silicon oxynitride, but the present invention is not limited to this. The spacer material layer 16 covers the insulating layer 11 in the high-voltage device region R1 and the sidewall and top surface of the gate sacrificial layer 14 in the logic region R2.

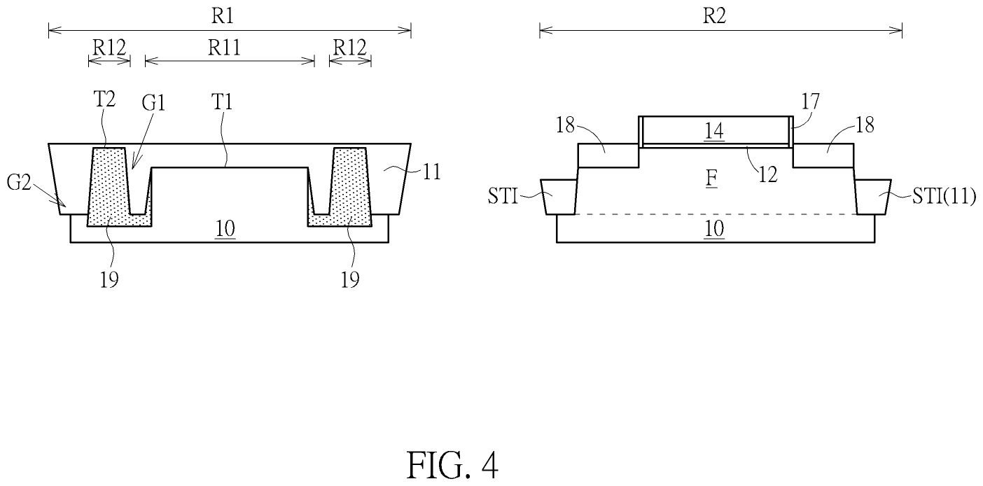

FIG. 4 is a schematic diagram showing the cross-sectional structure after the epitaxial layer is formed in the logic region. As shown in FIG. 4, part of the spacer material layer 16 in the logic region R2 is removed, and the remaining part of the spacer material layer 16 covers the sidewall of the gate sacrificial layer 14, and these remaining spacer material layers 16 are defined as spacers 17. In addition, an epitaxial layer 18, such as silicon germanium (SiGe) or silicon carbide (SiC), is formed in the fin structure F next to the gate sacrificial layer 14 in the logic region R2, but not limited thereto. The epitaxial layer 18 can be used as the source/drain region of the transistor subsequently formed in the logic region R2. Other related techniques for forming the epitaxial layer 18, which are known in the art, will not be described in detail here. In addition, preferably, after the epitaxial layer 18 is formed, the spacer material layer 16 in the high-voltage device region R1 is removed by a cleaning step, so that the surface of the insulating layer 11 is exposed again, but the present invention is not limited to this. In other embodiments of the present invention, the spacer material layer 16 may also be left in the high-voltage device region R1.

Before or after the step of forming an epitaxial layer in the logic region R2, a source/drain region 19 may be formed in the substrate 10 in the second region R12 in the high-voltage device region R1, and the source/drain region 19 may be formed by ion doping, for example. The gate structure formed in the subsequent high-voltage device region R1 is located between the source/drain regions 19.

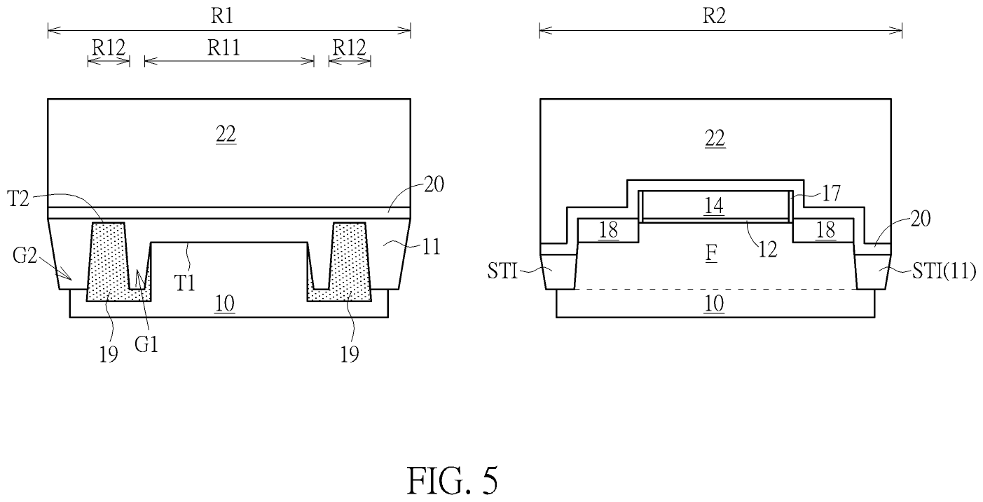

FIG. 5 shows a schematic cross-sectional structure after forming a contact etch stop material layer and a dielectric layer. As shown in FIG. 5, a contact etch stop material layer 20 and a dielectric layer 22 are continuously formed. The contact etch stop material layer 20 and dielectric layer 22 cover the insulating layer 11 in the high-voltage device region R1, while the contact etch stop material layer 20 and dielectric layer 22 cover the shallow trench isolation STI, the epitaxial layer 18, the spacers 17 and the gate sacrificial layer 14 in the logic region R2. In this embodiment, the contact etch stop material layer 20 is made of silicon nitride, for example, and the dielectric layer 22 is made of silicon oxide, for example, but not limited thereto.

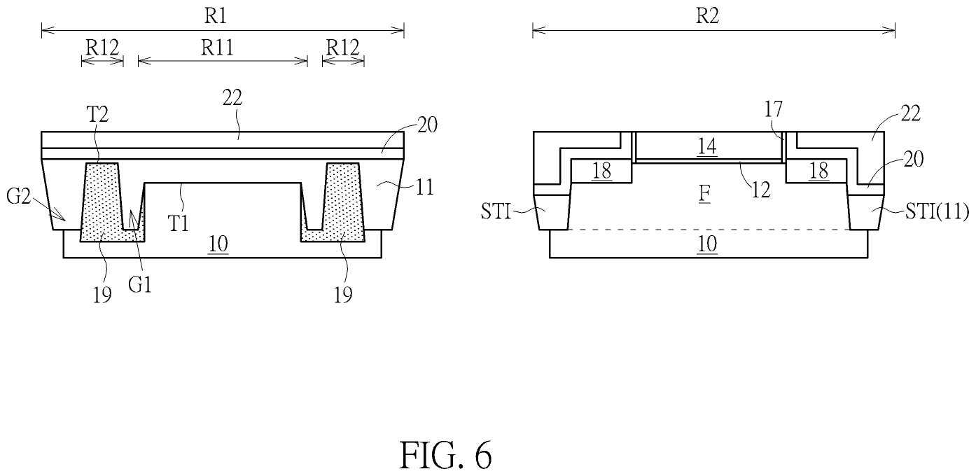

FIG. 6 is a schematic cross-sectional view showing the planarization step. In this embodiment, a planarization step, such as chemical mechanical polishing (CMP), is performed to remove part of the dielectric layer 22 and part of the contact etch stop material layer 20 in the logic region R2 until the top surface of the gate sacrificial layer 14 is exposed. At the same time, part of the dielectric layer 22 in the high-voltage device region R1 will also be removed in the planarization step.

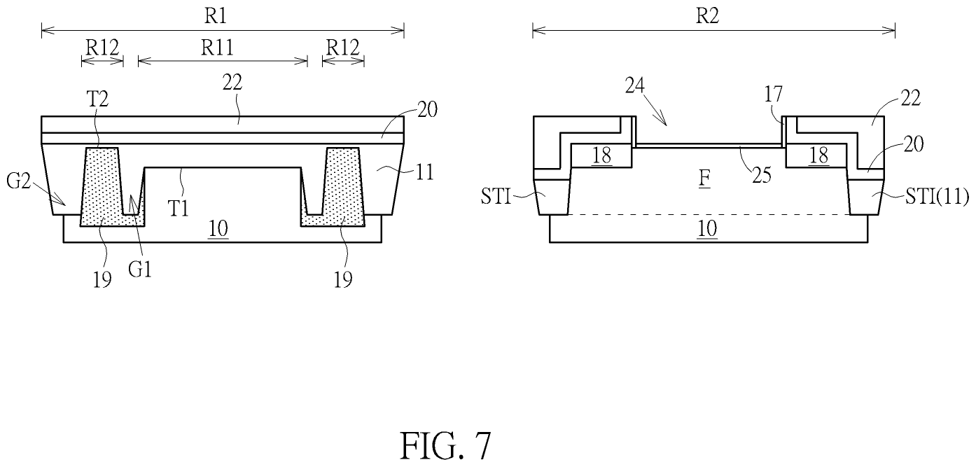

FIG. 7 shows a schematic cross-sectional structure after removing the gate sacrificial layer in the logic region. As shown in FIG. 7, the gate sacrificial layer 14 in the logic region R2 is removed, and a groove 24 is formed, in which the groove 24 will be filled with a plurality of material layers, such as an oxide layer, a high dielectric constant layer, a work function metal layer, a conductive layer, and the like. The material layers are sequentially formed in the groove 24 to form the gate structure in the logic region R2. In addition, in FIG. 7, when the gate sacrificial layer 14 is removed, the underlying oxide layer 12 may also be removed, and then another thermal oxidation step is used to regrow an oxide layer 25 on the bottom surface of the recess 24, but the present invention is not limited to this. In other embodiments of the present invention, the underlying oxide layer 12 can also be retained when the gate sacrificial layer 14 is removed, so it is not necessary to re-form the oxide layer 25, and this embodiment is also within the scope of the present invention.

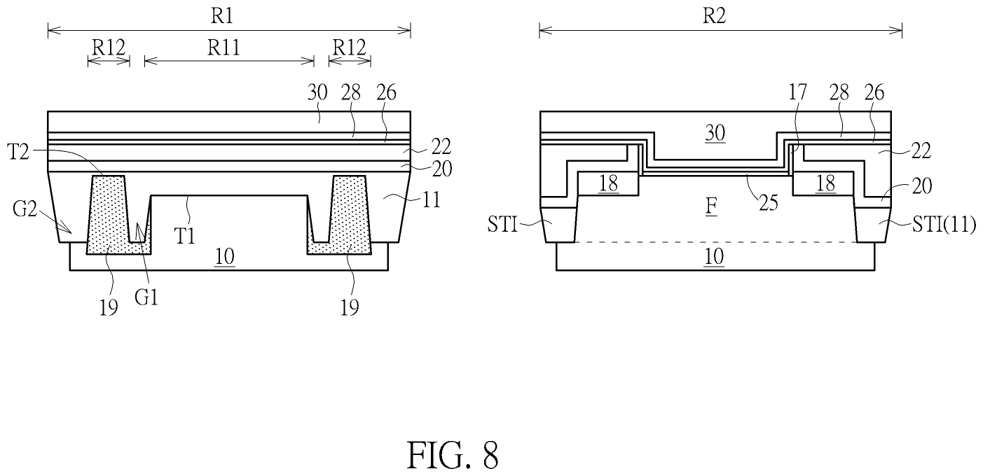

FIG. 8 shows a schematic cross-sectional structure of forming a multi-layer material layers and filling the multi-layer material layers into the gate groove in the logic region. As shown in FIG. 8, a high dielectric constant layer 26, a work function metal layer 28 and a gate conductive layer 30 are sequentially filled in the groove 24 of the logic region R2. The high dielectric constant layer 26 comprises a dielectric material with a dielectric constant greater than 4, for example, selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrxTi₁-xO₃, PZT), barium strontium titanate (BaxSr₁-xTiO₃, BST), or a combination thereof. The work function metal layer 28 can be titanium aluminide (TiAl), zirconium aluminide (ZrAl), tungsten aluminide (WAl), tantalum aluminide (TaAl), hafnium aluminide (HfAl), titanium aluminum carbide (TiAlC) or titanium nitride (TiN), tantalum nitride (TaN) or tantalum carbide (TaC), depending on whether the transistor in the logic region R2 is an N-type transistor. The gate conductive layer 30 contains a metal or metal oxide with excellent filling ability and low resistance, such as tungsten (W), aluminum (Al), titanium aluminum (TiAl) or titanium aluminum oxide (TiAlO). It can be understood that the above-mentioned material layers are only some examples of the present invention, and the present invention is not limited thereto.

In addition, it is worth noting that since the gate defining step (the step shown in FIG. 2) is not performed in the high-voltage device region R1, therefore no groove is formed in the high-voltage device region R1. Therefore, although the high dielectric constant layer 26, the work function metal layer 28 and the gate conductive layer 30 formed in FIG. 8 will also be formed in the high-voltage device region R1, these material layers are only located on the top surface of the dielectric layer 22 and will be removed in the subsequent steps.

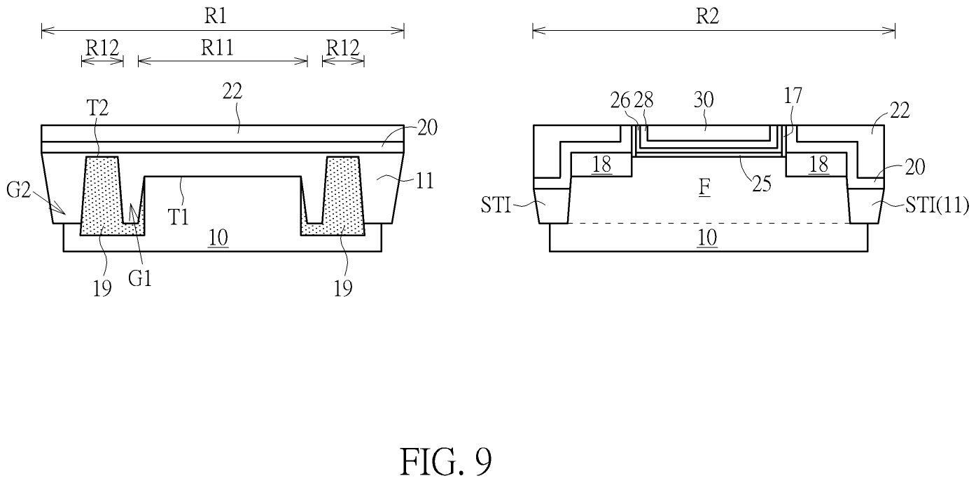

FIG. 9 is a schematic cross-sectional view showing another planarization step. As shown in FIG. 9, another planarization step is performed to remove the redundant high dielectric constant layer 26, the work function metal layer 28 and the gate conductive layer 30 on the top surface of the dielectric layer 22 in the logic region R2, and expose the top surface of the dielectric layer 22. Therefore, the groove 24 contains part of the oxide layer 25, the high dielectric constant layer 26, the work function metal layer 28 and the gate conductive layer 30, and forms the gate structure of the transistor. Until this step, the basic structure (including gate, source and drain) of the transistor in the logic region R2 has been completed, and contact structures will be formed in the subsequent step to electrically connect the transistor.

It is worth noting that after the planarization step shown in FIG. 9, the high dielectric constant layer 26, the work function metal layer 28 and the gate conductive layer 30 in the high-voltage device region R1 are also removed, exposing the top surface of the dielectric layer 22. As mentioned above, the gate defining step is not carried out in the high-voltage device region R1, so after a plurality of steps are carried out in the high-voltage device region R1, including the gate defining step (FIG. 2), forming the spacer material layer 16 (FIG. 3), forming the epitaxial layer 18 (FIG. 4), forming the contact etching stop material layer 20 (FIG. 5), forming the gate groove 24 (FIG. 6), and filling plurality of material layers in the groove 24 (FIG. 8), although these material layers may also be formed in the high-voltage device region R1, they are removed in the planarization step shown in FIG. 9. Therefore, after the gate structure in the logic region R2 (i.e., the oxide layer 25, the high dielectric constant layer 26, the work function metal layer 28 and the gate conductive layer 30 in the recess 24) is completed, the gate structure is still not formed in the high-voltage device region R1. One of the characteristics of the present invention is that the gate structure of the high-voltage device region R1 will be formed simultaneously with the subsequent slot contact structure, but not with the gate structure in the logic region R2.

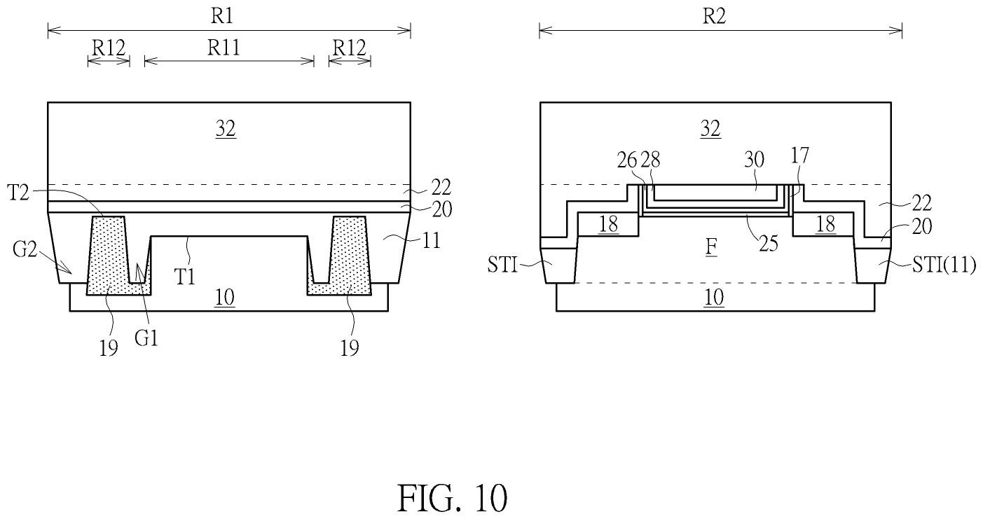

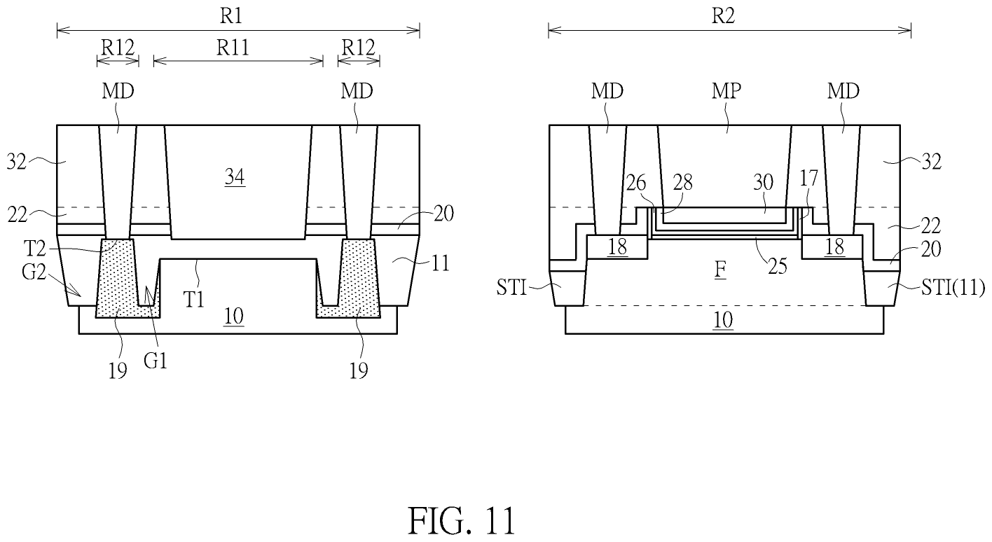

FIG. 10 shows a schematic cross-sectional structure after another dielectric layer is formed, and FIG. 11 shows a schematic cross-sectional structure after contact structures and a contact gate structure are formed. As shown in FIG. 10, another dielectric layer 32 is formed on the dielectric layer 22. The material of the dielectric layer 32 may be the same as that of the dielectric layer 22, such as, but not limited to, silicon oxide. Taking this embodiment as an example, the material of the dielectric layer 32 and the material of the dielectric layer 22 are both silicon oxide, so the interface between the two material layers is indicated by a dotted line. Then, as shown in FIG. 11, a plurality of slot contact structures are formed, wherein the slot contact structures include a first slot contact structure MD electrically connected to the source/drain region and a second slot contact structure MP electrically connected to the gate structure. The source/drain region here refers to the epitaxial layer 18 in the logic region R2 and the second region R12 in the high-voltage device region R1, while the gate structure here refers to the gate structure in the logic region R2 (the oxide layer 25, the high dielectric constant layer 26, the work function metal layer 28 and the gate conductive layer 30 in the recess 24, etc.).

In this embodiment, the main functions of the first slot contact structure MD and the second slot contact structure MP are to connect the terminals (gate, source and drain) of transistors to each other or to other electronic components (for example, to other transistors or voltage sources). In this embodiment, the materials of the first slot contact structure MD and the second slot contact structure MP are, for example, metals with good conductivity, such as tungsten, cobalt, copper, aluminum, gold, silver, etc., but not limited thereto.

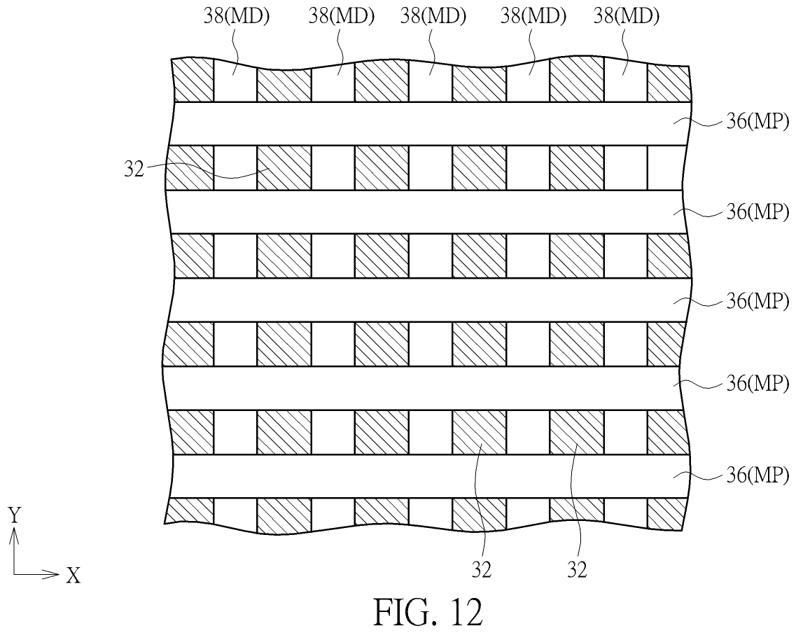

It is worth noting that in the process of forming the first slot contact structures MD and the second slot contact structures MP, a contact gate structure 34 is formed in the first region R11 in the high-voltage device region R1 at the same time. Please refer to FIG. 12, which shows a schematic view of the contact gate structure in the high-voltage device region of the present invention. In this embodiment, the contact gate structure 34 is composed of the first slot contact structures MD and the second slot contact structures MP. More specifically, in the process of forming the first slot contact structures MD and the second slot contact structures MP, the patterns of the first slot contact structures MD and the second slot contact structures MP are respectively transferred into the dielectric layer 32 by two photomasks (not shown), a plurality of strip-shaped openings (not shown) are formed in the dielectric layer 32, and then a metal layer is filled in the strip-shaped openings to form the first slot contact structures MD or the second slot contact structures MP. The present invention is characterized in that, in addition to forming the strip-shaped openings at the places where the first slot contact structures MD and the second slot contact structures MP are originally scheduled to be formed, the two masks respectively include a plurality of first patterns and a plurality of second patterns in the first region R11 in the high-voltage device region R1. After the first patterns and the second patterns are transferred to the dielectric layer 32, a plurality of corresponding first strip-shaped openings 36 arranged along a first direction (for example, horizontal direction or X direction) and a plurality of corresponding second strip-shaped openings 38 arranged along a second direction (for example, vertical direction or Y direction) in the dielectric layer 32 are formed, wherein the first strip-shaped openings 36 are arranged in parallel with each other, and the second strip-shaped openings 38 are also arranged in parallel with each other, and the first direction and the second direction are preferably perpendicular to each other. Therefore, a plurality of first strip-shaped openings 36 and a plurality of second strip-shaped openings 38 cross each other to form a grid-like pattern. However, the portion of the dielectric layer 32 where the first strip-shaped opening 36 or the second strip-shaped opening 38 is not formed, that is, the portion of the remaining dielectric layer 32 presents a plurality of independent columnar structures, and from the top view (FIG. 12), the plurality of remaining dielectric layers 32 are arranged in an array.

Next, as in the step of forming the first slot contact structure MD and the second slot contact structure MP, a metal layer is filled into the first strip-shaped opening 36 and the second strip-shaped opening 38 and other openings in the dielectric layer 32 (corresponding to other openings of the first slot contact structures MD and the second slot contact structures MP) to simultaneously complete the contact gate structure 34, the first slot contact structures MD and the second slot contact structures MP. From FIG. 12, although the first slot contact structures MD and the second slot contact structures MP are marked (that is, the first strip-shaped opening 36 and the second strip-shaped opening 38 are filled with metal layer respectively), in fact, since the metal layer is filled into the first strip-shaped openings 36 and the second strip-shaped openings 38 at the same time, the contact gate structure 34 is preferably an integrated structure composed of a single metal layer, in which a plurality of columnar dielectric layers 32 are located and arranged in an array.

It is worth noting that the contact gate structure 34 is formed by crossing the first strip-shaped openings 36 and the second strip-shaped openings 38 along two directions, and then filling the metal layer. The first strip-shaped opening 36 and the second strip-shaped opening 38 respectively correspond to two different mask patterns, and the corner of the part that does not overlap with the first strip-shaped opening 36 and the second strip-shaped opening 38 (that is, the left columnar dielectric layer 32) will be closer to a right angle. That is to say, the structure of the columnar dielectric layer 32 is relatively stable. In other embodiments, if the contact gate structure 34 is patterned with a single mask, the boundary of the columnar dielectric layer 32 will be seriously rounded, which is not conducive to the stability of the structure.

The contact gate structure 34 of the present invention is different from the general gate structure (for example, the gate structure in the logic region R2) in that it is composed of a single metal layer and is formed at the same time in the formation steps of the first slot contact structures MD and the second slot contact structures MP, so it contains the same metal material as the first slot contact structures MD and the second slot contact structures MP. In addition, both sides of the contact gate structure 34 do not contain material layers such as spacers, so the side of the contact gate structure 34 should directly contact the dielectric layer 22 and the dielectric layer 32. In addition, from the top view, the contact gate structure 34 contains a plurality of columnar dielectric layers 32 arranged in an array.

In practical application, the contact gate structure 34 is composed of a single metal layer and contains a plurality of columnar dielectric layers 32. Therefore, in the subsequent planarization step, the single metal material itself is not easy to be abraded, and the columnar dielectric layers 32 can also provide support, so the surface of the contact gate structure 34 is not easy to form defects such as dishing or metal residue.

Based on the above description and drawings, the present invention provides a semiconductor structure, which includes a substrate 10 defining a high-voltage device region R1, wherein the substrate 10 of the high-voltage device region R1 includes a first region R11, a first groove G1 surrounding the first region R11, and a second region R12 surrounding the first groove G1, and a contact gate structure 34 located in the high-voltage device region R1, wherein the contact gate structure 34 comprises a plurality of columnar dielectric layers 32 arranged in an array from a top view (FIG. 12).

In some embodiments of the present invention, the first region R11 of the substrate 10 has a first surface T1, and the second region R12 of the substrate has a second surface T2. The first surface T1 is lower than the second surface T2, and the materials of the first region R11 and the second region R12 are the same.

In some embodiments of the present invention, it further includes an insulating layer 11 covering the substrate 10.

In some embodiments of the present invention, the contact gate structure 34 is located on the insulating layer 11 and above the first region R11.

In some embodiments of the present invention, a dielectric layer 22 is further included, which is located on the insulating layer 11.

In some embodiments of the present invention, a slot contact structure MD is further included, which is located in the dielectric layer 22 and directly contacts the second surface T2 of the second region R12.

In some embodiments of the present invention, both the contact gate structure 34 and the slot contact structure MD are made of the same metal material.

In some embodiments of the present invention, the dielectric layer 22 directly contacts the metal material of the contact gate structure 34.

In some embodiments of the present invention, a bottom surface of the first groove G1 is lower than the first surface T1.

The present invention further provides a method for forming a semiconductor structure, which comprises providing a substrate 10 with a high-voltage device region R1 defined therein, wherein the substrate 10 of the high-voltage device region R1 comprises a first region R11, a first groove G1 surrounding the first region R11, and a second region R12 surrounding the first groove G1, and forming a contact gate structure 34 located in the high-voltage device region R1, wherein the contact gate structure 34 comprises a plurality of columnar dielectric layers 32 arranged in an array from a top view (FIG. 12).

In some embodiments of the present invention, a dielectric layer 22 is formed on the insulating layer 11.

In some embodiments of the present invention, a slot contact structure MD is formed, which is located in the dielectric layer 22 and directly contacts the second surface T2 of the second region R12.

In some embodiments of the present invention, the contact gate structure 34 and the slot contact structure MD are simultaneously formed in the dielectric layer 32, and both the contact gate structure 34 and the slot contact structure MD are made of the same metal material.

In some embodiments of the present invention, the dielectric layer 22/32 directly contacts the metal material of the contact gate structure MD.

In some embodiments of the present invention, forming the contact gate structure 34 further comprises forming a plurality of first strip-shaped openings 36 and a plurality of second strip-shaped openings 38 in the dielectric layer 32, wherein the first strip-shaped openings 36 are parallel to each other and arranged in a transverse direction, and the second strip-shaped openings 38 are parallel to each other and arranged in a longitudinal direction, and a metal material is filled in the first strip-shaped openings 36 and the second strip-shaped openings 38 to form the contact gate structure 34.

In some embodiments of the present invention, the substrate 10 further includes a logic region R2, and a gate structure (such as including the oxide layer 25, the high dielectric constant layer 26, the work function metal layer 28, and the gate conductive layer 30, etc.) is located in the logic region R2.

In some embodiments of the present invention, it further includes two spacers 17 located on both sides of the gate structure in the logic region R2.

The present invention is characterized by providing a semiconductor structure with a high-voltage device region and a logic region, wherein the gate structure of the high-voltage device region is not formed by the conventional gate patterning steps and processes such as replacing metal gates (including forming a gate sacrificial layer, defining the gate position, removing the gate sacrificial layer to form a gate groove, filling a plurality of layers of materials into the gate groove, etc.), but is formed at the same time as the slot contact structure. Therefore, the gate structure in the high-voltage device region is composed of a single layer of metal, which includes a plurality of columnar dielectric layers arranged in an array, and the two sides of the gate structure do not include spacers. The gate electrode in the high-voltage device region of the invention has good electrical properties, and it is not easy to produce phenomena such as dishing in the manufacturing process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure comprising:
a substrate defining a high-voltage device region, wherein the substrate of the high-voltage device region comprises a first region, a first groove surrounding the first region, and a second region surrounding the first groove; and
a contact gate structure located in the high-voltage device region, wherein the contact gate structure comprises a plurality of columnar dielectric layers arranged in an array from a top view.

2. The semiconductor structure according to claim 1, wherein the first region of the substrate has a first surface and the second region of the substrate has a second surface, the first surface is lower than the second surface, and the material of the first region is the same as the material of the second region.

3. The semiconductor structure according to claim 2, further comprising an insulating layer covering the substrate.

4. The semiconductor structure according to claim 3, wherein the contact gate structure is located on the insulating layer and above the first region.

5. The semiconductor structure according to claim 3, further comprising a dielectric layer located on the insulating layer.

6. The semiconductor structure according to claim 5, further comprising a slot contact structure located in the dielectric layer and directly contacting the second surface of the second region.

7. The semiconductor structure according to claim 6, wherein both the contact gate structure and the slot contact structure are made of a same metal material.

8. The semiconductor structure according to claim 7, wherein the dielectric layer directly contacts the metal material of the contact gate structure.

9. The semiconductor structure according to claim 2, wherein a bottom surface of the first groove is lower than the first surface.

10. A method for forming a semiconductor structure, comprising:
providing a substrate with a high-voltage device region defined therein, wherein the substrate of the high-voltage device region comprises a first region, a first groove surrounding the first region, and a second region surrounding the first groove; and
forming a contact gate structure located in the high-voltage device region, wherein the contact gate structure comprises a plurality of columnar dielectric layers arranged in an array from a top view.

11. The method for forming a semiconductor structure according to claim 10, wherein the first region of the substrate has a first surface and the second region of the substrate has a second surface, the first surface is lower than the second surface, and the first region and the second region are made of the same material.

12. The method for forming a semiconductor structure according to claim 11, further comprising forming an insulating layer covering the substrate.

13. The method for forming a semiconductor structure according to claim 12, further comprising forming a dielectric layer on the insulating layer.

14. The method for forming a semiconductor structure according to claim 13, further comprising forming a slot contact structure, which is located in the dielectric layer and directly contacts the second surface of the second region.

15. The method for forming a semiconductor structure according to claim 14, wherein the contact gate structure and the slot contact structure are simultaneously formed in the dielectric layer, and both the contact gate structure and the slot contact structure are made of a same metal material.

16. The method for forming a semiconductor structure according to claim 15, wherein the dielectric layer directly contacts the metal material of the contact gate structure.

17. The method for forming a semiconductor structure according to claim 13, wherein forming the contact gate structure further comprises:
forming a plurality of first strip-shaped openings and a plurality of second strip-shaped openings in the dielectric layer, wherein the first strip-shaped openings are parallel to each other and arranged in a transverse direction, and the second strip-shaped openings are parallel to each other and arranged in a longitudinal direction; and
filling a metal material in the first strip-shaped openings and the second strip-shaped openings to form the contact gate structure.

18. The method for forming a semiconductor structure according to claim 10, wherein the substrate further comprises a logic region, and a gate structure is located in the logic region.

19. The method for forming a semiconductor structure according to claim 18, further comprising two spacers located on both sides of the gate structure in the logic region.
